(19) United States
(12) Patent Application Publication
(10) Pub. No.: US 2002/0052093 A1
(43) Pub. Date: May 2, 2002

(54) Method of forming insulative trench

(76) Inventor: Horng-Huei Tseng, Hsin-Chu City (TW)

Correspondence Address: LOWE HAUPTMAN GOPSTEIN, GILMAN AND BERNER LLP, SUITE 310, 1700 DIAGONAL ROAD, ALEXANDRIA, VA, 22314

(21) Appl. No.: 09/982,996

(22) Filed: Oct. 22, 2001

Related U.S. Application Data
(63) Continuation-in-part of application No. 09/671,286, filed on Sep. 27, 2000, now abandoned.

(51) Int. Cl. H01L 21/76

(52) U.S. Cl. 438/424

(57) ABSTRACT

A method of forming insulative trench, at least including: a) forming a stacked layer over a substrate, where the stacked layer having an opening extending therethrough to expose a portion of the underlying substrate, moreover, the top of the stacked layer and the substrate have essentially similar material; b) removing the exposed portion of the underlying substrate to form an opening extending into the substrate; c) forming an insulative material with the opening in the substrate, where the insulative material within the opening forming an insulative plug with the substrate; and d) after forming the insulative material within the opening, removing the stacked layer and a portion of the insulative plug at the same time to let surface of the substrate is exposed and residual the insulative plug is located only in the substrate.

This application is a continuation-in-part of U.S. patent application Ser. No. 09/671,286, filed Sep. 27, 2000.

### BACKGROUND OF THE INVENTION

1. Field of the Invention

The invention pertains to methods of forming insulative trench, and can have particular application to method of forming insulative trench without disadvantages of parasitic devices that induced by gap adjacent to insulative trench, and also can have particular application to method of forming trench with simple and effective process.

2. Description of the Prior Art

In contemporary semiconductor device applications, numerous individual devices are packed onto a single small area of semiconductor substrate. Many of these individual devices need to be electrically isolated from one another, and one practical method of accomplishing such object is to form a trenched isolation or regions between adjacent devices. Such trenched isolation will generally comprise a trench or cavity formed within the substrate and filled with an insulative material, such as, silicon dioxide. Trench isolation regions are commonly divided into three categories: shallow trenches (trenches less than about one micro deep); moderate depth trenches (trenches of about one to about three microns deep); and deep trenches (trenches greater than about three microns deep).

One popular prior act method for forming insulative trench is described with reference to FIG. 1 through FIG. 5. Referring to FIG. 1, semiconductor wafer fragment 10 is shown at a preliminary stage of a prior art processing sequence. Wafer fragment 10 comprises substrate 12 upon which is formed oxide layer 14, nitride layer 16, and patterned photoresist 18. Available material of substrate 12 commonly comprises monocrystalline silicon, which is lightly doped with a conductivity-enhancing dopant. To aid in interpretation of the claims that follow, the term “substrate” is defined to mean any construction comprising semiconductive material, including, but not limited to, bulk semiconductive materials such as a semiconductive wafer (either along or in assemblies comprising other materials thereon), and semiconductive material layers (either alone or in assemblies comprising other materials). Moreover, substrate 12 comprises an upper surface 15, oxide layer 14 is formed over upper surface and typically comprises silicon oxide, nitride layer 16 is formed over oxide layer 14 and typically comprises silicon nitride.

Referring to FIG. 2, patterned photoresist layer 18 is used as a mask for an etching process. Herein, patterned photoresist layer 18 defines a hole region and the etching process removes part of nitride layer 16, part of oxide layer 14 and part of substrate 12 that are located in the hole region to form opening 20. In addition, the etching process can be divided into three sub-etching processes which corresponds to three different etched material: nitride layer 16, oxide layer 14 and substrate 12. Moreover, the timing of the etching process is adjusted to form opening 20 within substrate 12 to a desired depth. For instance, it opening 20 is to be shallow trench, the etching process will be timed to extend opening 20 to a depth of less than or equal to about one micron. However, although the details of the etching process are not key points of the method, the etch processes of three different materials indisputably let the steps of this method become more complicated.

Referring to FIG. 3, insulative material is formed on nitride layer 16 and in opening 20, and then part of insulative material and nitride layer 16 are removed in sequence. Herein, insulative material is different from material of nitride layer 16, and the difference allows part of insulative material, which located in opening 20, is not removed when nitride layer 16 is totally removed. Thus, a direct result is that insulative plug 30 is formed in and on substrate 12, and then insulative plug 30 can function as an insulative trench.

Referring to FIG. 4, oxide layer 14 is removed. An exemplary process for removing oxide layer 14 is a wet etch utilizing HF. As shown, the wet etch also has removed portions of insulative plug 30, owing to insulative material is different from nitride layer 16 and often-seen insulative material is either nitride or oxide, to recess edges of plug beneath upper surface 15 of substrate 12. According to, gaps 43 are formed between upper surface 15 and insulative plug 30. More specifically, insulative plug 30 comprises peripheral sidewalls 41 having portions 42 extending below upper surface 15 and portions 44 above upper surface 15. Portions 42 comprises low segments 45 which are against substrate 12 and upper segments 46 which are separated from substrate 12 by gaps 43.

Referring to FIG. 5, additional insulative layer 51 is grown over upper surface 15 (by, for example, thermal oxidation), and polysilicon layer 52 is formed over additional insulative layer 51. Polysilicon layer 52 can ultimately be formed into a wordline comprising transistor regions adjacent insulative plug 30, and then insulative plug 30 functions as a trench isolation region.

Anyway, gaps 43 can undesirably result in formation of parasitic devices adjacent the transistor devices and ultimately have an effect of lowing a threshold voltage for the transistor devices. Besides, gaps 43 also can interfere with subsequent fabrication processes. For the reason as well, it would be desirable to alleviate gaps 43.

Till now, some methods have been present for alleviating gaps 43, such as U.S. Pat. No. 6,093,652. One group of methods alleviates effects of gaps 43 by lowing surface of substrate 12 to first new upper surface 61 which is lower than upper surface 15, herein the upper surface is lower to let gaps 43 are vanished before additional insulative layer 51 etc. are formed, As FIG. 6 shows. Another group of methods alleviates effects of gaps 43 by removing portions of insulative plug 30, which is located over substrate 12, to let residual insulative plug 30 is totally against substrate 12 after gaps 43 are formed, as shown in FIG. 7, substrate adjacent to upper segment 46 also is removed and then surface of substrate 12 is changed from upper surface 12 to second upper surface 71, which is lower than the upper surface 12.

As a summary, each group of well-known methods for alleviating gaps 43 accompanies some disadvantages, and could not effectively form a trench inside several different layers which at least includes the substrate. Thus, it still is desirable to develop a method for alleviating these pending problems.

### SUMMARY OF THE INVENTION

Objects of the present invention at least include forming insulative trench without disadvantage of gaps which locates between insulative trench and substrate.

Objects of the present invention further comprise preventing formation of gaps during forming process of insulative trench.

Objects of the present invention also comprise effectively forming trenches inside several layers, which at least includes the substrate.

On the whole, one method present by the invention at least includes following basic steps: forming a first layer on a substrate; forming a second layer on the first layer, where the material of the second layer is essentially similar with the first layer; patterning both these layers and the substrate to form a trench which at least inside the second layer and the substrate. Herein, the etching receipt of the second layer is essentially similar with the etching receipt of the substrate.

Still a method of the present invention at least includes: forming a stacked layer over the substrate, the stacked layer having an opening extending therethrough exposing a portion of the substrate, moreover, the material of the upper part of the stacked layer is essentially similar with the material of the substrate, especially the material of the upper part of the substrate; removing the exposed portion of the substrate to form an opening extending into the substrate; forming an insulative material with the opening in the substrate to form an insulative plug; performing a removing process to remove both the stacked layer and a portion of the insulative plug simultaneously to let not only an upper surface of the substrate is exposed but also residual the insulative plug is only located in the substrate.

### BRIEF DESCRIPTION OF THE DRAWINGS

Preferred embodiments of the invention are described below with reference to the following accompanying drawings.

FIG. 1 to FIG. 5 are series of diagrammatic, cross-sectional, fragmentary views of a popular method for forming insulative trench;

FIG. 6 and FIG. 7 are two diagrammatic, cross-sectional, fragmentary views of two popular method for alleviating gaps which adjacent to insulative trench;

FIG. 8 is a flow chart of one preferred embodiment of the invention; and

FIG. 9A through FIG. 9G are some diagrammatic, cross-sectional, fragmentary views of another embodiment of the invention.

### DESCRIPTION OF THE PREFERRED EMBODIMENT

This disclosure of the invention is submitted in furtherance of the constitutional purpose of the U.S. Patent Laws “to promote the progress of science and useful arts” (Article 1, Section 8).

First of all, the Applicant of the claimed invention emphasizes that it is better to prevent formation of gaps that to alleviate gaps. That is to say, the new approach about forming insulative trench without disadvantages of gaps should focus on how to form insulative trench without formation of gaps at the same time. In contrast, almost all well-known methods focus on how to eliminate existent gaps, the old approach is intuitive and direct for it is not necessary to modify forming process of insulative trench, but the old approach always meets with existence of gaps. Besides, the new approach always never meets with existence of gaps but is necessary to modify forming process of insulative trench. However, when available semiconductor fabricating process is more advanced than ancient times, modification of corresponding forming process is not difficult.

Sequentially, the Applicant of the claimed invention emphasizes following viewpoints: if a trench is formed inside several layers at the same time, except these layers that would be remained in the final structure, material of other temporary layers, which only appear during the fabrication of the final structure, could be adjusted to balance the requirement of high efficiency etching process and other functions. Therefore, it is better to let the material(s) of all temporary layer(s) be equivalent to simplify the fabrication of a trench insider several layers, at least owing to essentially same etching receipt can be used by several different layers.

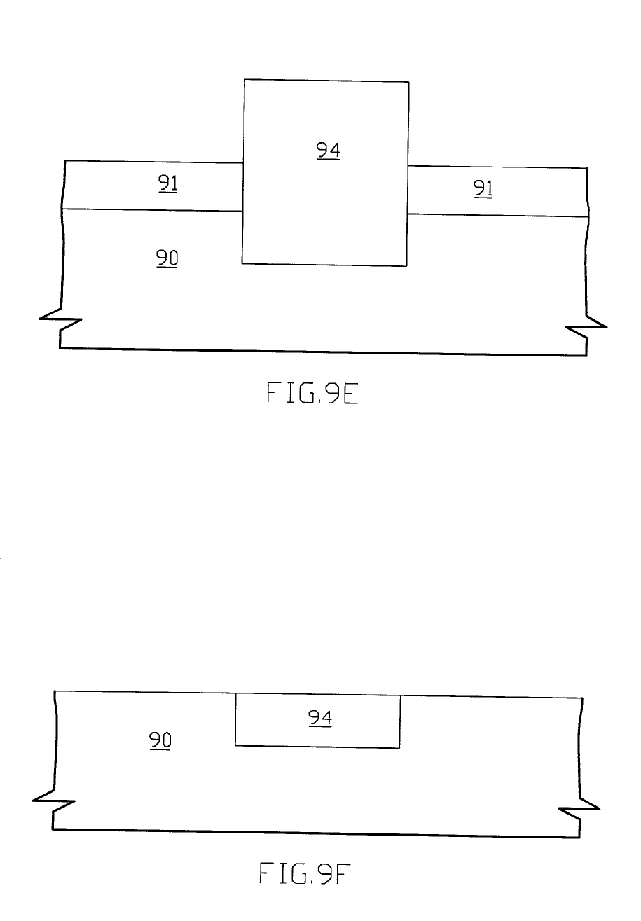

One preferred embodiment of the invention relates to a method for forming a trench. Referring to FIG. 8, the method comprises some essential steps: Firstly, as stack block 81 shows, sequentially forms a first layer, a second layer, and a patterned photoresist over a substrate. Herein, the first layer could be used to prevent the damage(s) between different layers. Further, the material of the second layer usually is essentially similar with the material of the substrate. For example, while the substrate is a silicon substrate, the second layer could be a silicon layer, a polysilicon layer, or an amorphous silicon layer. Secondly, as etching block 82 shows, etching these layers and the substrate by using the patterned photoresist as a mask. Herein, because the etching receipt of the second layer is essentially similar with the etching receipt of the substrate, the total etching process is simplified for only two etching receipts, the etching receipt of the first layer and the receipt of the second layer, are required to form a trench inside there elements: second layer, first layer, and substrate.

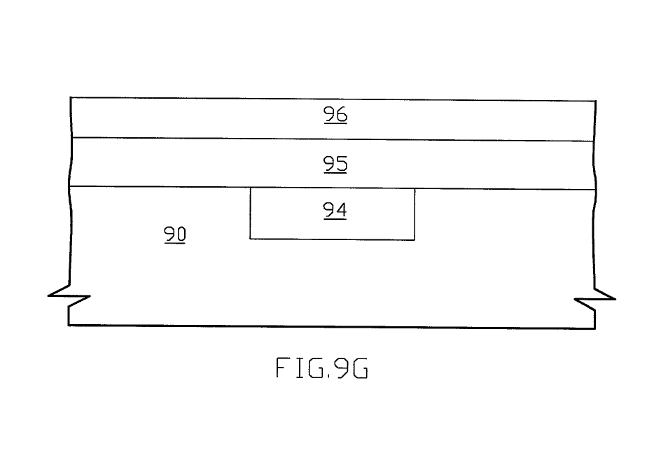

Another embodiment of the present invention is described with reference to FIG. 9A through FIG. 9G.

As FIG. 9A shows, form a stacked layer, which is a combination of first layer 91 and second layer 92, and patterned photoresist 93 over substrate 90. Whereby the material of second layer is essentially similar with the material of substrate 90. Further, first layer 91 usually is an oxide layer and could be used to prevent the damage(s) between adjacent layers, second layer 92 usually is a silicon layer whose material usually is essentially similar with the material of substrate 90, such as polysilicon or amorphous silicon. Moreover, patterned photoresist 93 has an opening that exposes partial of underlying stacked layer.

As FIG. 9B shows, use patterned photoresist 93 as a mask to etch the stacked layer and substrate 90, and then a trench is formed inside both the stacked layer and substrate 90.

Note that because second layer 92 and substrate 90 have essentially similar materials, the forming process of the trench is effectively simplified for only two etching processes, etching process for removing the material of second layer 92 and etching process for removing the material of first layer 91, are required to remove three adjacent structures: layers 91/92 and substrate 90.

As FIG. 9C shows, remove residual photoresist 93 and fill the opening by insulative material 935 935. In addition, the proximate surface of substrate 90 is an outmost surface of substrate 90, the insulative plug 94 has a sidewall within the trench and against substrate 90.

As FIG. 9D shows, remove partial insulative material 935 on the planar of the stacked layer to expose the stacked layer so let insulative plug 94 is formed both inside the trench and on the stacked layer. As usually, chemical mechanical polish process is used to remove partial insulative material 935.

As FIG. 9E shows, remove second layer 92.

As FIG. 9F shows, perform a removing process to remove both first layer 91 and a portion of the insulative plug 94 in a horizontal direction until residual insulative plug 94 is only located inside substrate 90. Moreover, the removing process usually is a chemical mechanical polish process, and could further comprises treating the polished surface by a wet etch process after a portion of the insulative plug 94 is removed to repair scars that locates in/on substrate 90 and is formed during removal of portions of insulative plug 94.

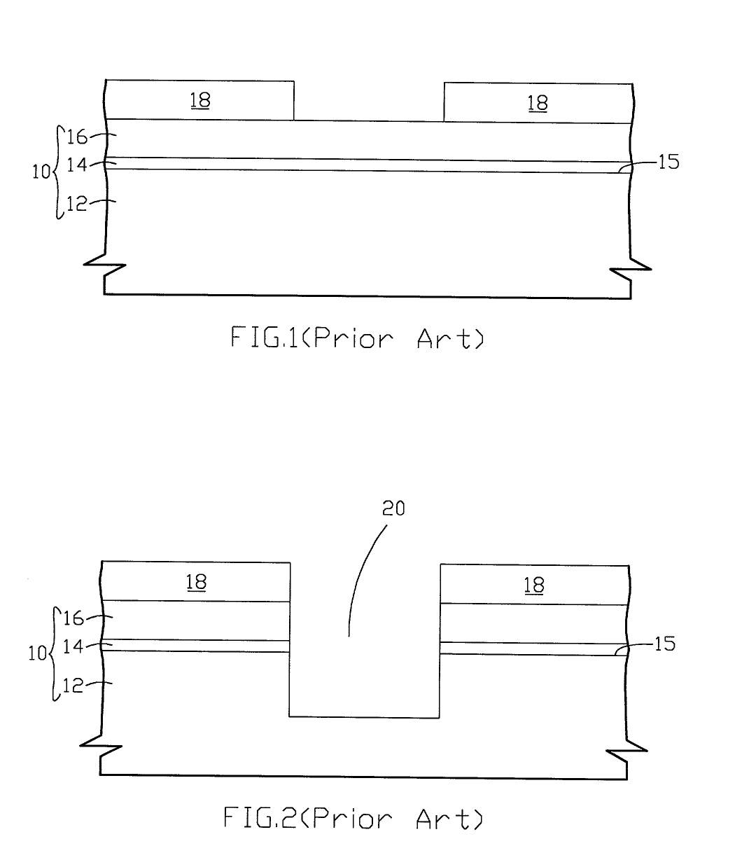

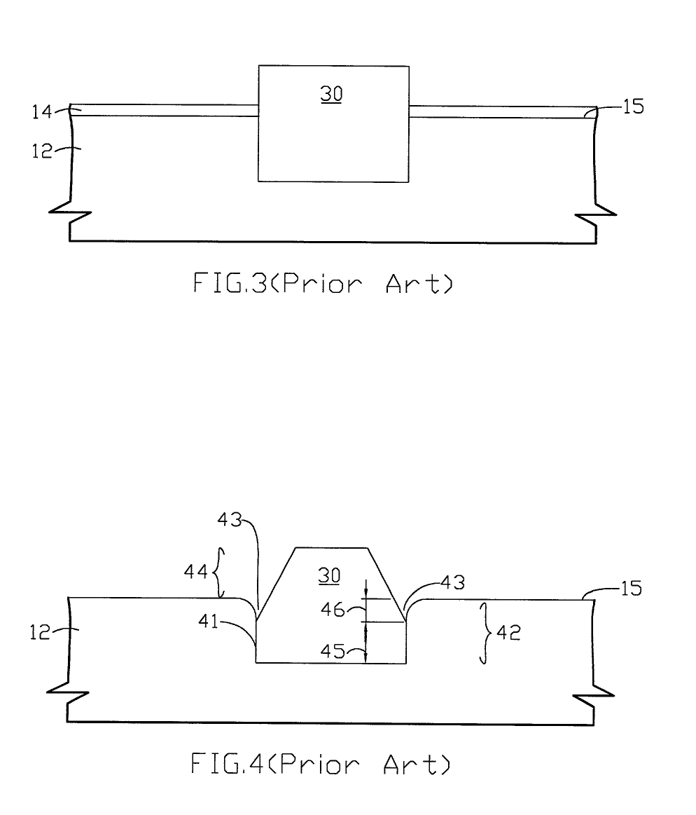

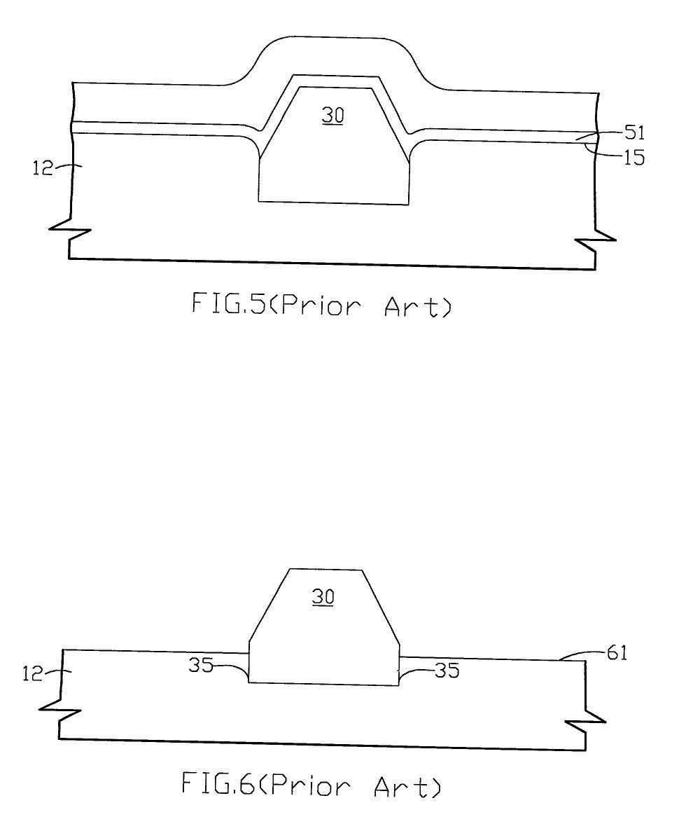

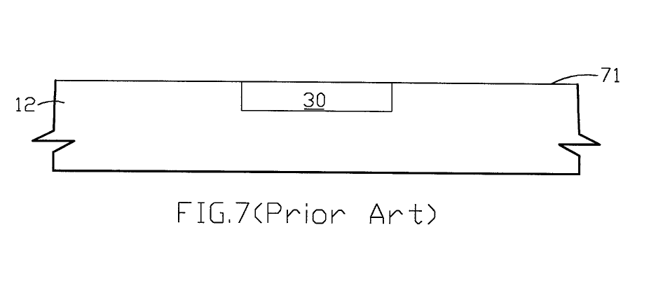

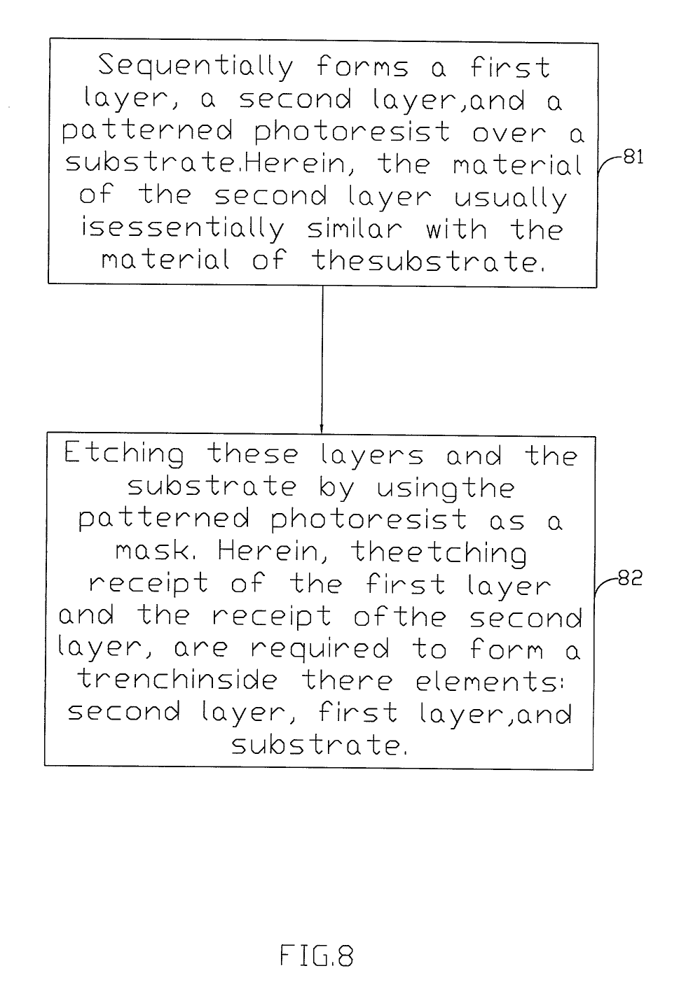

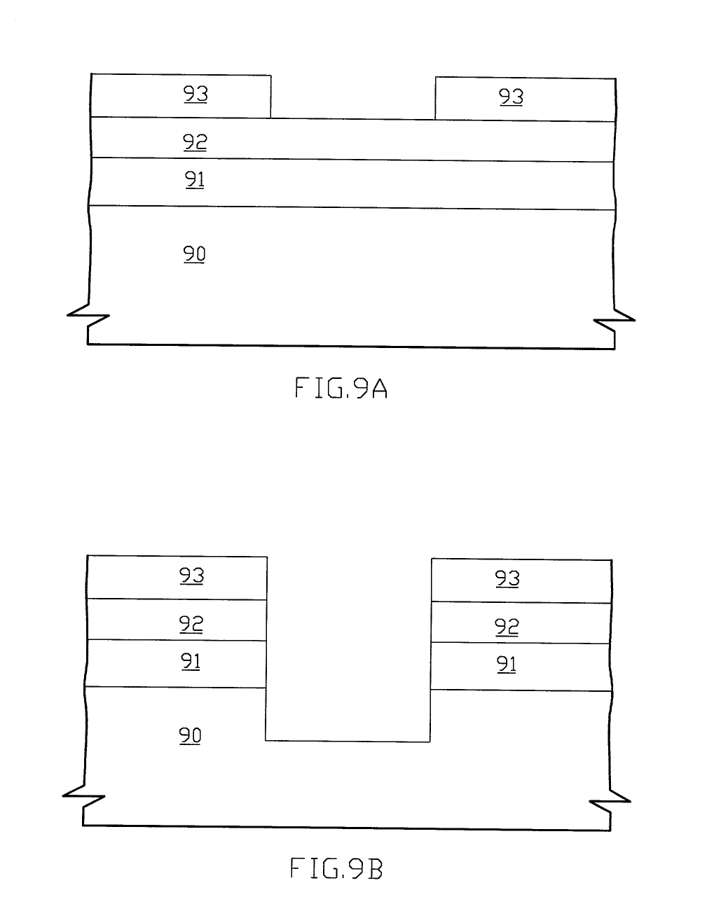

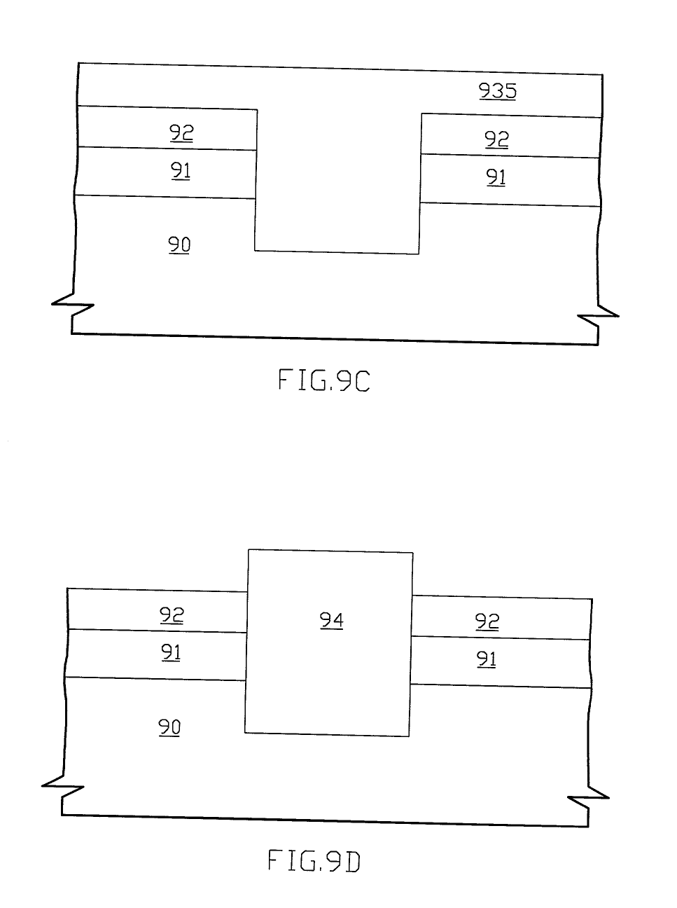

By comparing FIGS. 9A through 9F with FIG. 1 through FIG. 7, a significant difference could be found: for conventional technologies, insulative plug 30 is located in and on substrate 12, such as silicon semiconductor substrate, and gaps 43 are existent between substrate 12 and residual insulative plug 94 30; for this invention, the insulative plug 94 of the invention is only located in substrate 90 and there is no gap between substrate 90 and residual insulative plug 94 of this invention. Further, it should be noted that upper surface 15a is independent on the upper surface 901 of substrate 90 of FIG. 9F.

Therefore, as FIG. 9G shows, while additional insulative layer 95 and polysilicon layer 96 are formed in sequence over the upper surface 901, it is crystal-clear that no parasitic device will be formed by non-existent gap.

Note that the removal of a portion of insulative plug 94 30 and oxide layer 14 is accomplished at the same by an planarizing process, and is preferably accomplished with a chemical mechanical polish process, which can remove different material 935s simultaneously without effect of etch selective for the material 935 of substrate 12 relative to the material 935 of insulative plug 94 30, which is the source of gaps 43 in conventional methods. In other words, conventional method uses etch, especially wet etch, to remove oxide layer 14 and then the etch selective between oxide layer 14 and insulative plug 94 30 induces existence of gaps 43, but the present invention uses other ways to remove oxide layer 14 and portions of insulative layer 30 at the same time, and then the etch selective between oxide layer 14 and insulative plug 94 30 does not induce any gap. Certainly, owing to planarizing process may induce some scars on upper surface 15a, the present invention further comprises an optional step that treats upper surface 15a by a wet etching process to repair all scars.

Further, for practical application of the embodiment, thickness of first layer, which usually is an oxide layer, usually is about from 100 angstroms to 500 angstroms, thickness of second layer, which usually is silicon layer, usually is about from 1000 angstroms to 3000 angstroms, and the insulative layer usually is a silicon dioxide layer.

Finally, to compare to other conventional methods, advantages of the claimed invention at least includes that it is not desirable to remove portion of substrate and then structures in substrate, such as doped regions, will not be damage, and it is not desirable to remove oxide layer and portions of insulative plug 94 in two stages.

In compliance with the statute, the invention has been described in language more or less specific as to structural and methodical features. It is to be understood, however, that the invention is not limited to the specific features shown and described, since the means herein disclosed comprises preferred forms of putting the invention into effect. The invention is, therefore, claimed in any of its form or modifications within the proper scope of the appended claims appropriately interpreted in accordance with the doctrine of equivalents.

What is claimed is:

1. A method of forming a trench in a substrate, comprising:
providing a substrate;
forming a first layer over said substrate;
forming a second layer over said first layer, wherein the material of said second layer is essentially similar with the material of said substrate;
forming a patterned photoresist over said second layer, said patterned photoresist exposing a portion of said second layer, a portion of said first layer, and a portion of said substrate;
etching said second layer, said first layer, and said substrate in sequence by using said patterned photoresist as a mask, so let a hole is formed inside said second layer, said first layer, and said substrate.

2. The method of claim 1, wherein said first layer is an oxide layer.

3. The method of claim 1, wherein said second layer is a silicon layer.

4. The method of claim 1, wherein the material of said second layer is chosen from the group consisting of polysilicon and amorphous silicon.

5. The method of claim 1, wherein the receipt for etching said second layer is essentially similar with the receipt for etching said substrate.

6. A method of forming an insulative trench in a substrate, comprising:
forming a stacked layer over said substrate, wherein the material of the upper part of said stacked layer is essential similar with the material of said substrate;
patterning said stacked layer to let an opening extending therethrough exposing a portion of said substrate;
removing said exposed portion of said substrate to form an opening extending into said substrate;
forming an insulative material with said opening in said substrate to form an insulative plug; and
performing a removing process to remove both said stacked layer and a portion of said insulative plug simultaneously to let not only an upper surface of said substrate is exposed but also residual said insulative plug is only located in said substrate.

7. The method of claim 1, wherein said stacked layer is stacked by an oxide layer and a silicon layer in sequence.

8. The method of claim 7, wherein said silicon layer is chosen from the group consisting of polysilicon layer and amorphous silicon layer.

9. The method of claim 6, wherein said insulative material is formed both inside said opening and on said stacked layer.

10. The method of claim 6, further comprises removing said insulative material from over said stacked layer before performing said removing process.

11. The method of claim 6, wherein said stacked layer is removed by a chemical mechanical polish process.

12. The method of claim 6, wherein said removing process is a chemical mechanical polish process.

13. The method of claim 6, whereby residual said insulative plug comprises a peripheral sidewall that against said substrate after said removing process is finished.

14. A method of forming an isolation, comprising:
providing a silicon substrate;
forming an oxide layer on said substrate;
forming a silicon layer on said oxide layer;
patterning said silicon layer, said oxide layer and said substrate to form an opening which extending therethrough said substrate;
forming a insulative layer within said opening to form a insulative plug;
removing said silicon layer; and
performing a removing process to remove both said oxide layer and a portion of said insulative plug in a horizontal direction until residual said insulative plug is only located inside said substrate.

15. The method of claim 14, wherein said silicon layer is chosen from the group consisting of polysilicon layer and amorphous silicon layer.

16. The method of claim 14, wherein thickness of said oxide layer is about from 100 angstroms to 500 angstroms.

17. The method of claim 14, wherein said insulative layer is a silicon dioxide layer.

18. The method of claim 14, wherein said silicon layer is removed by a chemical mechanical polish process.

19. The method of claim 14, wherein said removing process is a chemical mechanical polish process.

20. The method of claim 14, further comprises forming gate oxide layer on gate electrode on both said substrate and residual said insulative plug in sequence after said removing process is finished.
